(19) United States
(12) Patent Application Publication
(10) Pub. No.: US 2014/0145193 A1
(43) Pub. Date: May 29, 2014

(54) LEAD FRAME AND POWER MODULE

(71) Applicants: Takuya Kadoguchi, Toyota-shi (JP); Tatsuya Miyoshi, Nagoya-shi (JP); Takanori Kawashima, Anjo-shi (JP); Tomomi Okumura, Toyota-shi (JP)

(72) Inventors: Takuya Kadoguchi, Toyota-shi (JP); Tatsuya Miyoshi, Nagoya-shi (JP); Takanori Kawashima, Anjo-shi (JP); Tomomi Okumura, Toyota-shi (JP)

(73) Assignees: DENSO CORPORATION, Kariya-shi (JP); TOYOTA JIDOSHA KABUSHIKI KAISHA, Toyota-shi (JP)

(21) Appl. No.: 14/129,342

(22) PCT Filed: Apr. 26, 2012
(86) PCT No.: PCT/JP2012/061272

§ 371 Date: Dec. 26, 2013

(30) Foreign Application Priority Data
Jun. 28, 2011 (JP) 2011-143033

(51) Int. Cl. H01L 21/66; H01L 23/495

(52) U.S. Cl. CPC H01L 22/34; H01L 23/495
USPC 257/48

(57) ABSTRACT

A problem to be solved is to provide a lead frame and a power module having high material yield.

A lead frame includes a plurality of first leads extending to one side of an area in which a semiconductor device is disposed in a planar view; a plurality of second leads extending to another side that is opposite the one side of the area in which the semiconductor device is disposed in a planar view; a third lead arranged outside of one of the plurality of first leads positioned at an edge of the plurality of first leads in a planar view; and a wiring part that is connected to the third lead, acts as a part of a guide frame of the plurality of first leads, the plurality of second leads, and the third lead, and acts as a wiring connected to the third lead after parts of the guide frame other than the part of the guide frame have been cut off.

### TECHNICAL FIELD

The present invention is related to a lead frame and a power module.

### BACKGROUND ART

Conventionally, there is a lead frame in which at least an island for mounting a semiconductor chip, a lead connected to the semiconductor chip via a bonding wire, and a tie bar for tying the island and the lead to the lead frame main body, are formed by forming open windows in the lead frame main body. In the lead frame, reinforcing projections are provided on the outer peripheral part of the lead frame main body (see, for example, Patent Document 1).

### PRIOR ART DOCUMENT

Patent Document 1: Japanese Laid-Open Patent Publication No. 2008-218455

### SUMMARY OF INVENTION

### Problem to be Solved by Invention

Incidentally, in a conventional lead frame, after forming mold resin, the outer peripheral part is cut off and discarded, and therefore there has been a problem in that the material yield is low.

Therefore, an objective is to provide a lead frame and a power module having high material yield.

### Means to Solve the Problem

A lead frame according to an embodiment of the present invention includes a plurality of first leads extending to one side of an area in which a semiconductor device is disposed in a planar view; a plurality of second leads extending to another side that is opposite the one side of the area in which the semiconductor device is disposed in a planar view; a third lead arranged outside of one of the plurality of first leads positioned at an edge of the plurality of first leads in a planar view; and a wiring part that is connected to the third lead, acts as a part of a guide frame of the plurality of first leads, the plurality of second leads, and the third lead, and acts as a wiring connected to the third lead after parts of the guide frame other than the part of the guide frame have been cut off.

### Effects of the Invention

A lead frame and a power module having high material yield can be provided.

### BRIEF DESCRIPTION OF DRAWINGS

FIG. 1 illustrates a state where IGBTs 20A through 20C and diodes 30A through 30C are connected to a lead frame 10 of a comparative example.

FIG. 2 illustrates a power module 60 of the comparative example.

FIG. 3 illustrates a schematic configuration of an electric automobile driving device 300 including a power module 200 according to one embodiment.

FIG. 4A is an oblique perspective view of a lead frame 100 and the power module 200 according to the embodiment.

FIG. 4B is an oblique view of the power module 200 according to the embodiment.

FIG. 5A is a plan perspective view of the power module 200 including the lead frame 100 according to the embodiment.

FIG. 5B is a plan perspective view of the power module 200 in a state where a guide frame 119 is cut off from the lead frame 100 of FIG. 5A and the power module 200 is completed.

FIG. 6 is a cross-sectional view cut along C-C in FIG. 5B.

FIG. 7 illustrates manufacturing procedures of the power module 200 according to the embodiment in a stepwise manner.

FIG. 8 illustrates manufacturing procedures of the power module 200 according to the embodiment in a stepwise manner.

FIG. 9 illustrates manufacturing procedures of the power module 200 according to the embodiment in a stepwise manner.

FIG. 10 illustrates manufacturing procedures of the power module 200 according to the embodiment in a stepwise manner.

FIG. 11 illustrates manufacturing procedures of the power module 200 according to the embodiment in a stepwise manner.

### BEST MODE FOR CARRYING OUT THE INVENTION

In the following, a description is given of an embodiment to which a lead frame and a power module according to the present invention are applied.

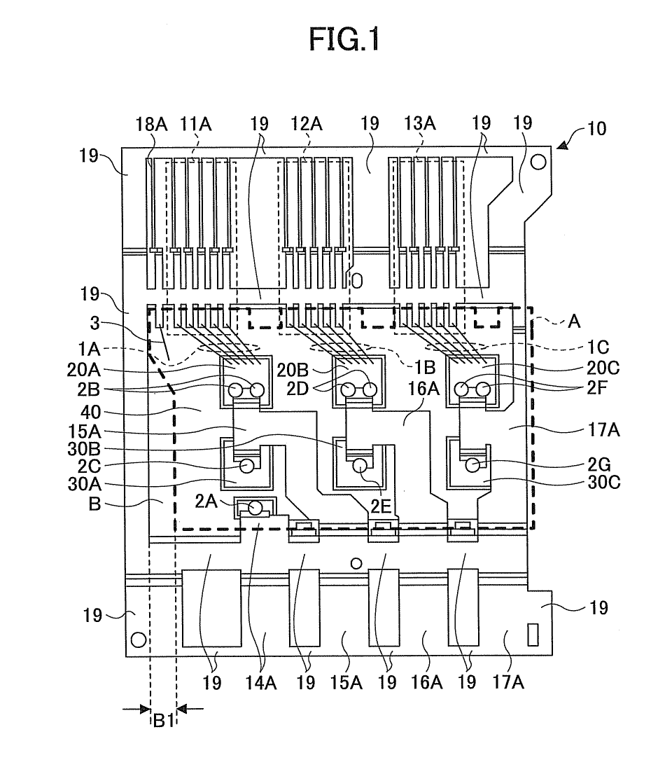

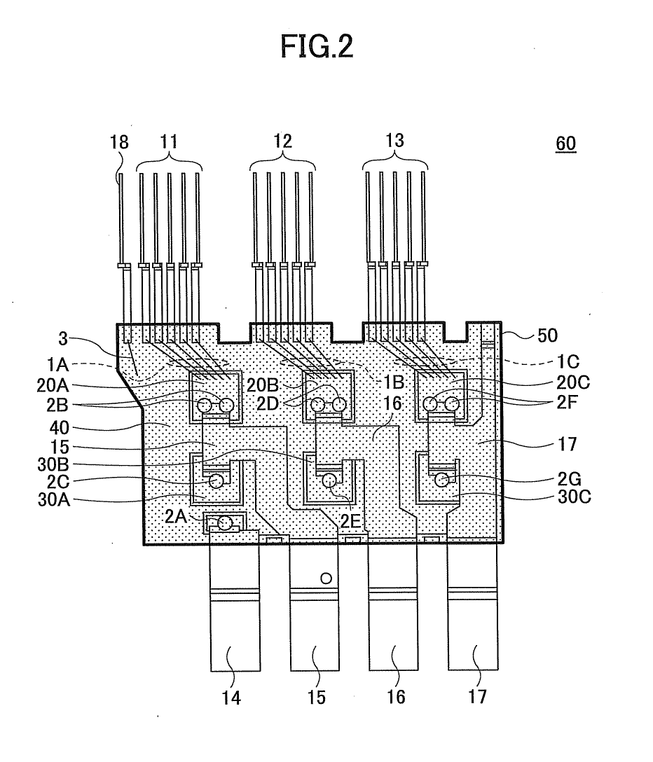

First, before describing a lead frame and a power module according to an embodiment, a description is given of a lead frame of a comparative example, with reference to FIGS. 1 and 2.

FIG. 1 illustrates a state where IGBTs (Insulated Gate Bipolar Transistor) 20A through 20C and diodes 30A through 30C are connected to a lead frame 10 of a comparative example. As the diodes 30A through 30C, for example, FWDs (Fly Wheel Diode) may be used.

The lead frame 10 of the comparative example includes signal lead parts 11A, 12A, 13A, power lead parts 14A, 15A, 16A, 17A, and a voltage detection lead part 18A. In the lead frame 10, by cutting off a part later, the parts other than the parts remaining as the signal lead parts 11, 12, 13, the power lead parts 14, 15, 16, 17, and a voltage detection lead part 18 (see FIG. 2), function as a guide frame 19.

The above-described lead frame 10 is manufactured by, for example, press-processing a copper plate.

The IGBTs 20A through 20C and the diodes 30A through 30C are soldered to the top side of a heat spreader 40. FIG. 1 illustrates a state where the lead frame 10 is covering, from the top side, the IGBTs 20A through 20C and the diodes 30A through 30C mounted on the heat spreader 40, and the IGBTs 20A through 20C and the diodes 30A through 30C are connected to the lead frame 10 by bonding wire and soldering.

In the following, the IGBTs 20A through 20C are simply referred to as the IGBT 20 when they are not particularly distinguished among each other. Similarly, the diodes 30A through 30C are simply referred to as the diode 30 when they are not particularly distinguished among each other.

The heat spreader 40 is made of, for example, a copper plate, and the IGBTs 20A through 20C and the diodes 30A through 30C are provided for radiating heat.

Collector terminals of the IGBTs 20A through 20C at the bottom side in FIG. 1 are connected to the heat spreader 40 by soldering. Cathodes of the diodes 30A through 30C at the bottom side in FIG. 1 are connected to the heat spreader 40 by soldering.

There are five signal lead parts 11A, which are connected to the gate terminal of the IGBT 20A by a bonding wire 1A. There are five signal lead parts 12A, which are connected to the gate terminal of the IGBT 20B by a bonding wire 1B. There are five signal lead parts 13A, which are connected to the gate terminal of the IGBT 20C by a bonding wire 1C.

The power lead part 14A is connected to the surface of the heat spreader 40 by a solder 2A. The power lead part 15A is connected to the emitter terminal of the IGBT 20A by a solder 2B, and is connected to the anode of the diode 30A by a solder 2C.

The power lead part 16A is connected to the emitter terminal of the IGBT 20B by a solder 2D, and is connected to the anode of the diode 30B by a solder 2E. The power lead part 17A is connected to the emitter terminal of the IGBT 20C by a solder 2F, and is connected to the anode of the diode 30C by a solder 2G.

The voltage detection lead part 18A is connected to the edge part of the surface of the heat spreader 40 by a bonding wire 3.

As illustrated in FIG. 1, after connecting the lead frame 10, the IGBTs 20, and the diodes 30, a mold resin part is formed by transfer molding in an area indicated by a dashed line A, and the guide frame 19 of the lead frame 10 is cut off, so that a power module 60 of the comparative example illustrated in FIG. 2 is completed.

FIG. 2 illustrates the power module 60 of the comparative example.

The power module 60 includes the signal lead parts 11, 12, 13, the power lead parts 14, 15, 16, 17, the voltage detection lead part 18, the IGBTs 20, the diodes 30, the heat spreader 40, and a mold resin part 50.

The signal lead parts 11, 12, 13, the power lead parts 14, 15, 16, 17, and the voltage detection lead part 18 illustrated in FIG. 2 correspond to the signal lead parts 11A, 12A, 13A, the power lead parts 14A, 15A, 16A, 17A, and the voltage detection lead part 18A illustrated in FIG. 1, respectively.

The signal lead parts 11, 12, 13, the power lead parts 14, 15, 16, 17, and the voltage detection lead part 18 illustrated in FIG. 2 are formed by cutting off the guide frame 19 from the lead frame 10 illustrated in FIG. 1.

The signal lead parts 11, 12, 13, the power lead parts 14, 15, 16, 17, the voltage detection lead part 18, the IGBT 20, the diodes 30, and the heat spreader 40 are fixed by the mold resin part 50.

The mold resin part 50 is manufactured by, for example, molding a thermosetting epoxy resin while applying heat.

As described above, when manufacturing the power module 60, the lead frame 10 including the guide frame 19 is used in order to increase the positioning precision of the signal lead parts 11, 12, 13, the power lead parts 14, 15, 16, 17, and the voltage detection lead part 18.

The power module 60 as described above may be used as, for example, an upper arm of an inverter. Furthermore, in this case, a power module similar to the power module 60 may be used as the bottom arm of the inverter. The power module used as the bottom arm may be formed by, for example, removing the voltage detection lead part 18 from the power module 60.

The power lead parts 15, 16, 17 of the power module 60 of the top arm of the inverter, and three phases of the power lead parts of the power module of the bottom arm, are connected to a three-phase motor, so that drive control of the three-phase motor can be performed.

As described above, the voltage detection lead part 18A illustrated in FIG. 1 is connected to the edge part of the surface of the heat spreader 40 by the bonding wire 3. To the heat spreader 40, the collector terminals of the IGBTs 20 are soldered, and therefore the heat spreader 40 has the same potential as the collector terminals of the IGBTs 20.

Therefore, the voltage detection lead part 18, which is formed by cutting off the guide frame 19 from the lead frame 10, is connected to the collector terminals of the IGBTs 20 of the top arm of the inverter.

The collector terminals of the IGBTs 20 of the top arm of the inverter have the same potential as the positive terminal of the inverter, and therefore the voltage of the positive terminal of the inverter can be detected through the voltage detection lead part 18.

Incidentally, as can be seen by comparing FIGS. 1 and 2, the lead frame 10 used in the power module 60 of the comparative example includes many parts that are discarded as the guide frame 19. Therefore, the lead frame 10 used in the power module 60 of the comparative example has a problem in that the material yield is low.

Furthermore, the linear expansion coefficient of the lead frame 10 made of copper is significantly greater than the linear expansion coefficient of the mold resin part 50. Accordingly, when heat is applied for molding the mold resin part 50, and the power module 60 is cooled after forming the mold resin part 50, the guide frame 19 contracts more so than the mold resin part 50. Therefore, a deformation occurs in the signal lead parts 11, 12, 13, the power lead parts 14, 15, 16, 17, and the voltage detection lead part 18.

Furthermore, in the power module 60 of the comparative example, when cutting off the guide frame 19, a thin mold used for the cutting is inserted in an area B between the mold resin part 50 (see FIG. 2) and the guide frame 19.

As illustrated in FIG. 1, a width B1 of the area B is narrow, and therefore, for example, a problem arises in that when metal friction is generated in the thin mold, a burr is formed in the mold resin part 50.

Furthermore, in order to connect the voltage detection lead part 18 to the surface of the heat spreader 40 with the bonding wire 3, a process of forming the bonding wire 3 needs to be performed, which causes problems in that the number of manufacturing processes is increased and the cost of the power module 60 is increased.

In the following, a description is given of a lead frame 100 and a power module 200 according to an embodiment in which the above problems are solved.

### Embodiment

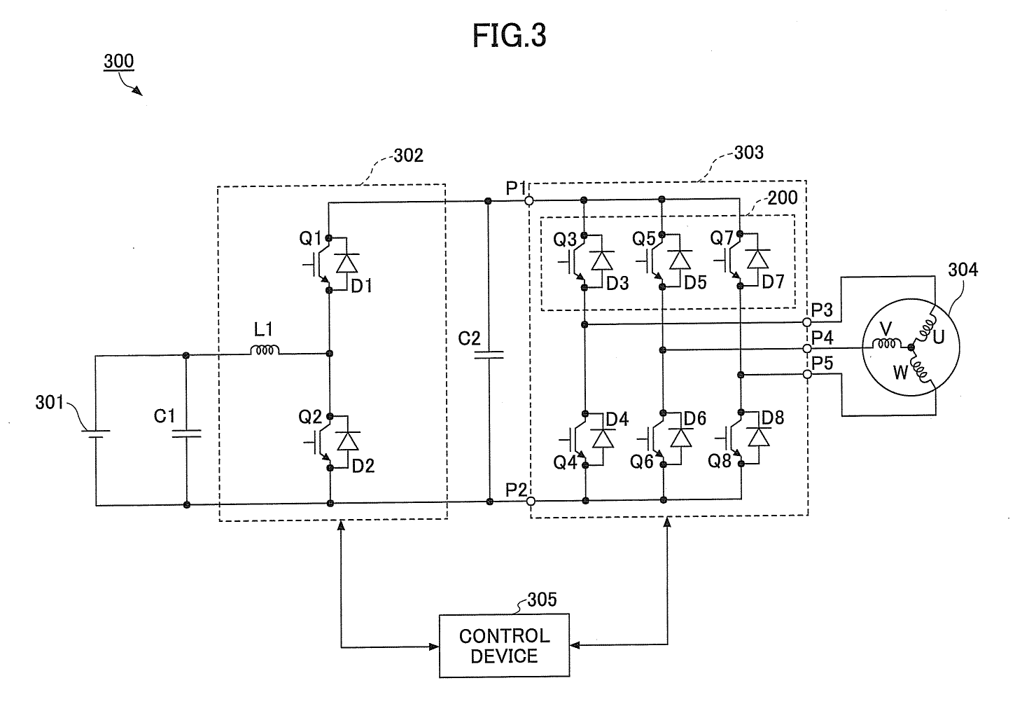

FIG. 3 illustrates a schematic configuration of an electric automobile driving device 300 including the power module 200 according to one embodiment.

The electric automobile driving device 300 is a device for driving a vehicle by driving a running motor 304 using power of a battery 301. Note that as long as the electric automobile runs by driving the running motor 304 using power, specific methods and configurations of the electric automobile are arbitrary. Electric automobiles typically include a hybrid automobile (HV) in which the power source is a motor and the running motor 304, and an electric automobile in which the power source is only the running motor 304.

As illustrated in FIG. 3, the electric automobile driving device 300 includes a battery 301, a DC/DC converter 302, an inverter 303, a running motor 304, and a control device 305.

The battery 301 is an arbitrary storage device for storing power and outputting a DC voltage, and may be constituted by a capacitive load such as a nickel hydride battery, a lithium ion battery, and an electric double-layer capacitor.

The DC/DC converter 302 is a bidirectional DC/DC converter (a boost DC/DC converter of a reversible chopper method). For example, the DC/DC converter 302 is capable of step-up conversion from 14 V to 42 V, and step-down conversion from 42 V to 14V. The DC/DC converter 302 includes switching elements Q1, Q2, diodes D1, D2, and a reactor L1.

The switching elements Q1, Q2 are IGBTs (Insulated Gate Bipolar Transistor) in the present example; however, other switching elements may be used such as MOSFETs (Metal Oxide Semiconductor Field-Effect Transistor).

The switching elements Q1, Q2 are serially connected between the positive line and the negative line of the inverter 303. The collector of the switching element Q1 of the top arm is connected to the positive line, and the emitter of the switching element Q2 of the bottom arm is connected to the negative line. At the middle point between the switching elements Q1, Q2, i.e., at the connection point of the emitter of the switching element Q1 and the collector of the switching element Q2, one end of the reactor L1 is connected. The other end of the reactor L1 is connected to the positive electrode of the battery 301 via the positive line. Furthermore, the emitter of the switching element Q2 is connected to the negative electrode of the battery 301 via the negative line. Furthermore, between the collectors and the emitters of the switching elements Q1, Q2, the diodes (flywheel diodes) D1, D2 are respectively disposed, so that a current flows from the emitter side to the collector side. Furthermore, between the other end of the reactor L1 and the negative line, a smoothing capacitor C1 is connected, and between the collector of the switching element Q1 and the negative line, a smoothing capacitor C2 is connected.

The inverter 303 is constituted by the respective arms of a U phase, a V phase, and a W phase disposed in parallel to each other between the positive line and the negative line. The U phase is constituted by a serial connection of switching elements (IGBTs in the present example) Q3, Q4, the V phase is constituted by a serial connection of switching elements (IGBTs in the present example) Q5, Q6, and the W phase is constituted by a serial connection of switching elements (IGBTs in the present example) Q7, Q8. Furthermore, between the collectors and the emitters of the switching elements Q3 through Q8, diodes (flywheel diodes) D3 through D8 are respectively disposed, so that a current flows from the emitter side to the collector side. The top arm of the inverter 303 is constituted by the switching elements Q3, Q5, Q7 and the diodes D3, D5, D7, and the bottom arm of the inverter 303 is constituted by the switching elements Q4, Q6, Q8 and the diodes D4, D6, D8.

The inverter 303 is realized by including, for example, the power module 200 as the top arm. As the bottom arm of the inverter 303, a power module of an arbitrary format including the switching elements Q4, Q6, Q8 and the diodes D4, D6, D8, may be used.

The running motor 304 is a permanent magnet motor of three phases, in which the one of the ends of three coils of the U phase, the V phase, and the W phase are connected to each other at a midpoint. The other end of the U phase coil is connected to the middle point of the switching elements Q3, Q4, the other end of the V phase coil is connected to the middle point of the switching elements Q5, Q6, and the other end of the W phase coil is connected to the middle point of the switching elements Q7, Q8.

The control device 305 controls the DC/DC converter 302 and the inverter 303. The control device 305 includes, for example, a CPU, a ROM, and a main memory, and various functions of the control device 305 are implemented as a control program, which is recorded in the ROM, etc., is loaded in the main memory and executed by the CPU. However, part of or the entirety of the control device 305 may be realized only by hardware. Furthermore, the control device 305 may be physically constituted by a plurality of devices.

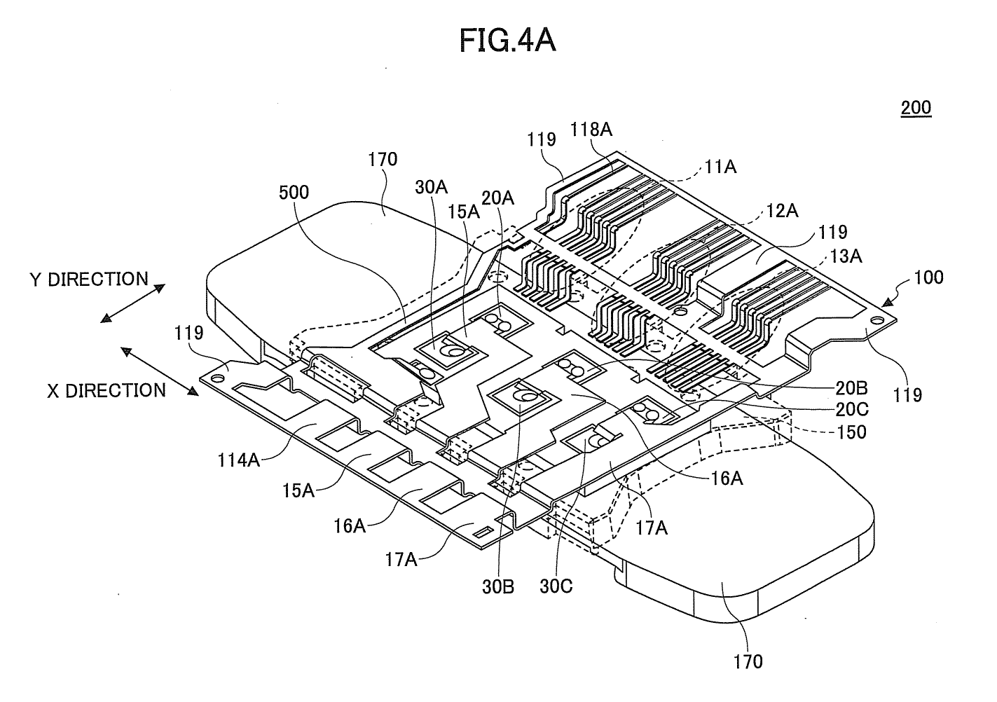

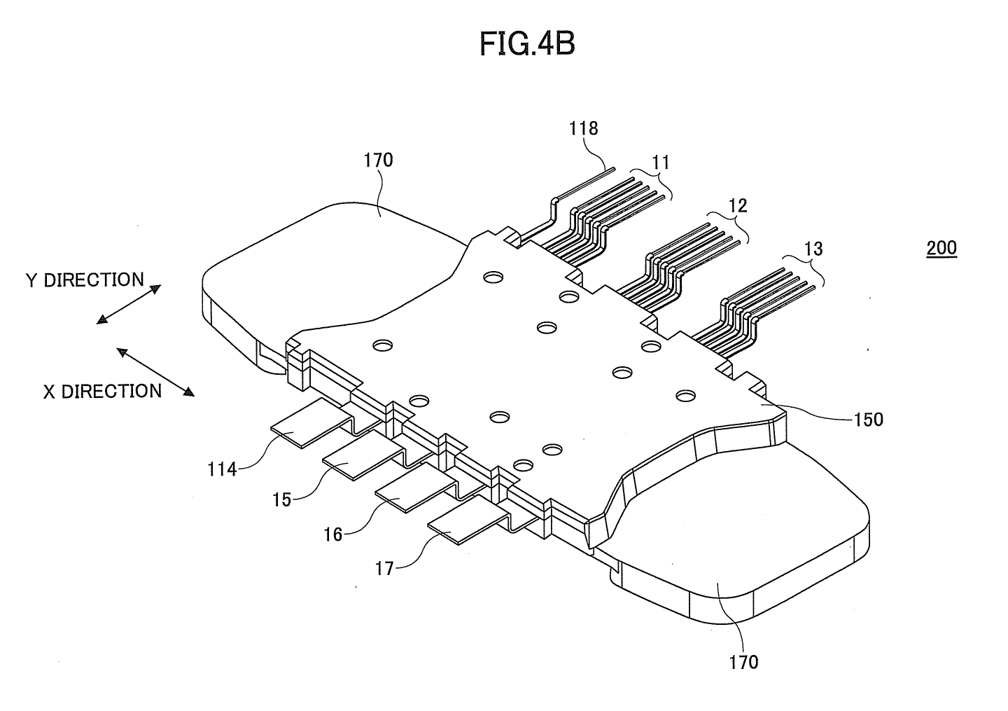

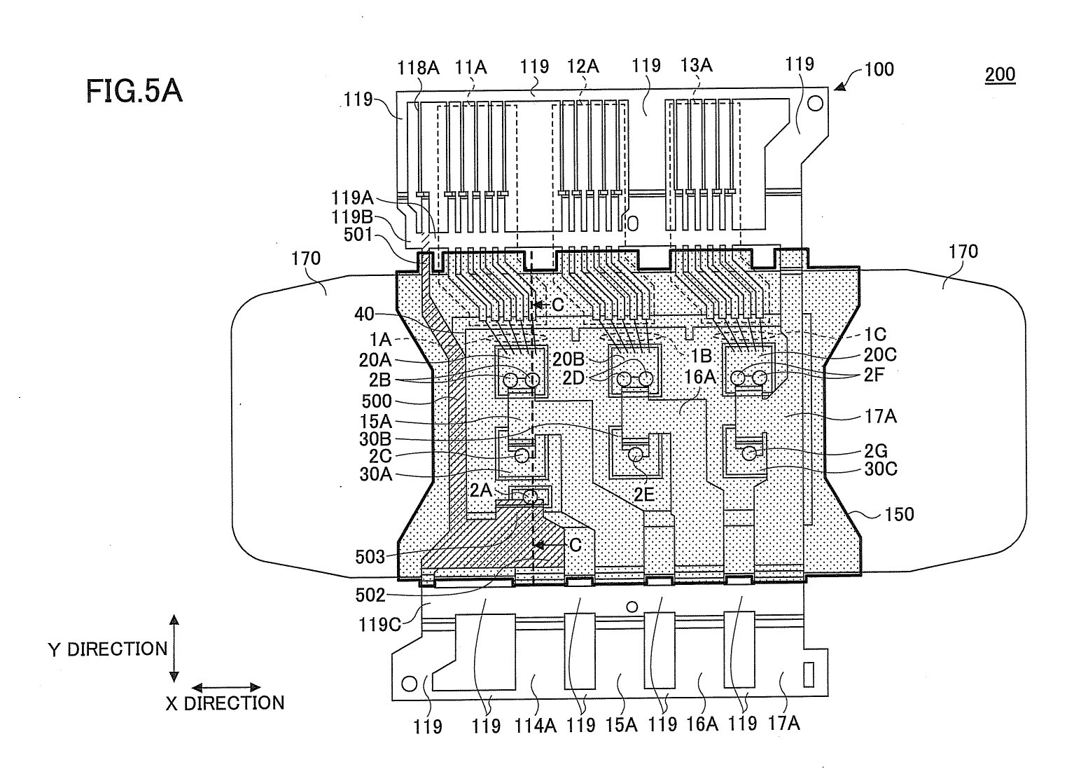

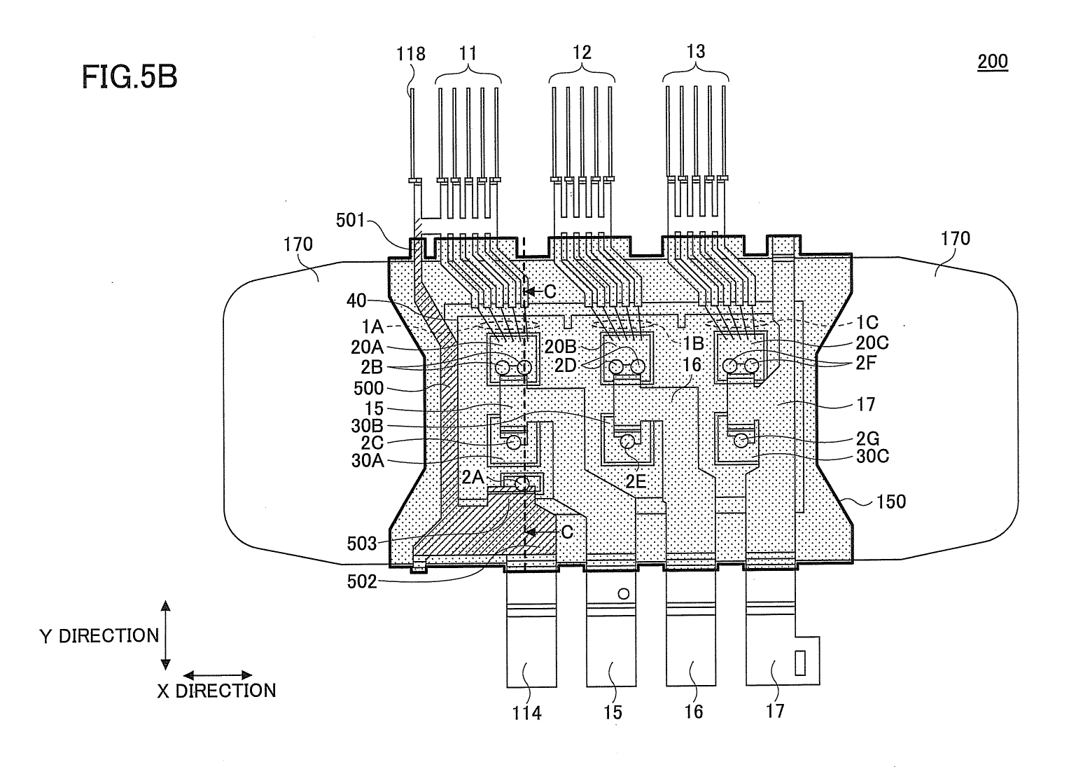

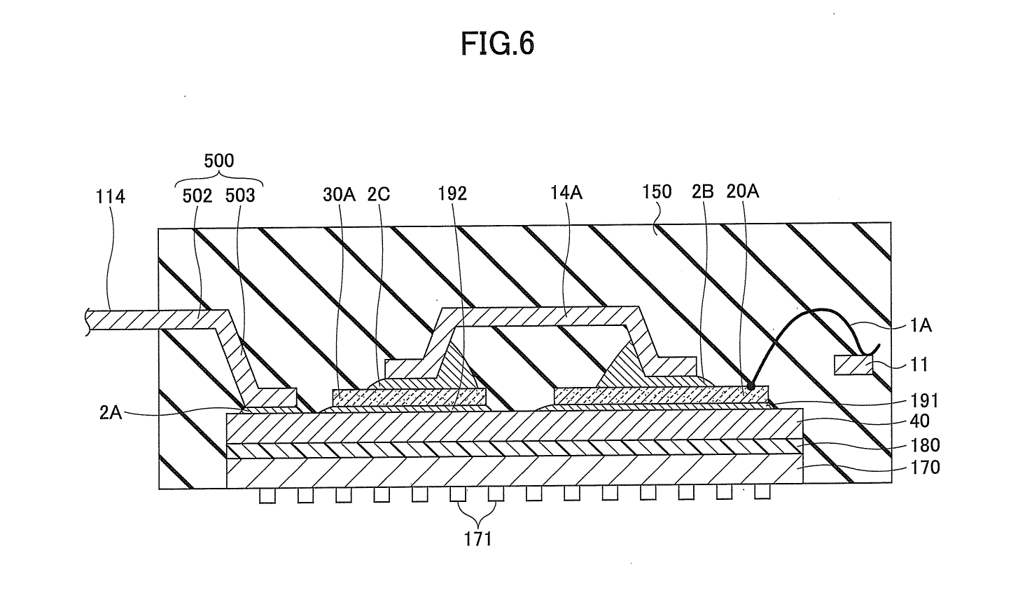

Next, a description is given of the lead frame 100 and the power module 200 according to an embodiment, with reference to FIG. 4A, FIG. 4B, FIG. 5A, FIG. 5B, and FIG. 6.

FIG. 4A is an oblique perspective view of the lead frame 100 and the power module 200 according to the embodiment. FIG. 4B is an oblique view of the power module 200 according to the embodiment.

FIG. 5A is a plan perspective view of the power module 200 including the lead frame 100 according to the embodiment. FIG. 5B is a plan perspective view of the power module 200 in a state where a guide frame 119 is cut off from the lead frame 100 of FIG. 5A and the power module 200 is completed.

FIG. 6 is a cross-sectional view cut along C-C in FIG. 5B.

FIGS. 4A and 5A illustrate the lead frame 100 and the power module 200 in a state before the guide frame 119 of the lead frame 100 is cut off. FIGS. 4B and 5B illustrate the power module 200 in a state after the guide frame 119 of the lead frame 100 is cut off and the power module 200 is completed.

In the lead frame 100 and the power module 200 illustrated in FIG. 4A, FIG. 4B, FIG. 5A, and FIG. 5B, elements that are the same as those of the lead frame 10 and the power module 60 of the comparative example illustrated in FIG. 1 and FIG. 2 are denoted by the same reference numerals and descriptions thereof are omitted.

The power module 200 includes, as main elements, the lead frame 100, the IGBTs 20A through 20C, the diodes 30A through 30C, the heat spreader 40, a mold resin part 150, a cooling plate 170, and an insulating sheet 180.

Similar to the power module 60 of the comparative example, the IGBTs 20A through 20C and the diodes 30A through 30C of the power module 200 are soldered on the heat spreader 40.

For example, as illustrated in FIG. 6, the IGBT 20A is connected to the surface of the heat spreader 40 by a solder 191. On the bottom side of the IGBT 20A that is connected to the heat spreader 40 by the solder 191, there is a collector terminal, and therefore, the collector terminal of the IGBT 20A is connected to the heat spreader 40 by the solder 191.

Furthermore, the diode 30A is connected to the heat spreader 40 by a solder 192. On the bottom side of the diode 30A that is connected to the heat spreader 40 by the solder 192, there is a cathode, and therefore, the cathode of the diode 30A is connected to the heat spreader 40 by the solder 192.

FIG. 6 is a cross-sectional view including the IGBT 20A; however, similar to the IGBT 20A, the IGBTs 20B, 20C are connected to the heat spreader 40 by the solder 191, in a state where the collector terminal is placed at the bottom face. Furthermore, similar to the diode 30A, the diodes 30B, 30C are connected to the heat spreader 40 by the solder 192, with the cathode placed at the bottom face.

The heat spreader 40, on which the IGBTs 20A through 20C and the diodes 30A through 30C are soldered, is connected to the lead frame 100, and is sealed by the mold resin part 150 molded by transfer molding, in a state where the heat spreader 40 is placed on the cooling plate 170 via the insulating sheet 180.

As illustrated in FIG. 4A and FIG. 5A, the lead frame 100 includes the signal lead parts 11A, 12A, 13A, the power lead parts 114A, 15A, 16A, 17A, and in addition, a voltage detection lead part 118A, the guide frame 119, and a wiring part 500.

The signal lead parts 11A, 12A, 13A are examples of a first lead part. The power lead parts 15A, 16A, 17A are examples of a second lead part.

The voltage detection lead part 118A is an example of a third lead part. The wiring part 500 is an example of a wiring part connected to the third lead part. The power lead part 114A is an example of a fourth lead part.

The lead frame 100 is manufactured by, for example, by press-processing a copper plate.

The voltage detection lead part 118A corresponds to the voltage detection lead part 18A in the lead frame 10 of the comparative example.

When the guide frame 119 illustrated in FIG. 4A and FIG. 5A is cut off from the lead frame 100, the voltage detection lead part 118A becomes a voltage detection lead part 118 illustrated in FIG. 4B and FIG. 5B.

The voltage detection lead part 118A is arranged on the outside of the signal lead part positioned at the edge of the signal lead parts 11A, 12A, 13A (the signal lead part disposed at the leftmost side of the five signal lead parts 11A).

The wiring part 500 is the part indicated by hatching in FIG. 5A and FIG. 5B, including one end 501, another end 502, and a connection part 503.

The one end 501 is connected to the voltage detection lead part 118A on the outside of the mold resin part 150. The other end 502 is connected to the power lead part 114A. The connection part 503 is connected to the surface of the heat spreader 40 by a solder 2A.

As illustrated in FIG. 5B and FIG. 6, in the wiring part 500, the one end 501 is positioned outside the mold resin part 150; however, parts other than the one end 501 are sealed by the mold resin part 150.

As illustrated in FIG. 5B and FIG. 6, the power lead part 114A is the part connected to the other end 502 of the wiring part 500 and positioned outside the mold resin part 150. The power lead part 114A is positioned at the outermost side among the power lead parts 15, 16, 17, and is arranged on the outside of the power lead part 15 corresponding to the signal lead part positioned at the edge of the signal lead parts 11A, 12A, 13A (the signal lead part disposed at the leftmost side of the five signal lead parts 11A).

The signal lead parts 11, 12, 13, the power lead parts 114, 15, 16, 17, the voltage detection lead part 118, and the wiring part 500 illustrated in FIG. 4B and FIG. 5B are respectively obtained by cutting off the guide frame 119 from the lead frame 100 including the signal lead parts 11A, 12A, 13A, the power lead parts 114A, 15A, 16A, 17A, the voltage detection lead part 118A, and the wiring part 500 illustrated in FIG. 4A and FIG. 5B.

That is to say, the guide frame 119 included in the lead frame 100 according to the embodiment, is the part that has disappeared in FIG. 5B, from the lead frame 100 illustrated in FIG. 5A.

There are five signal lead parts 11A, which are connected to the gate terminal of the IGBT 20A by the bonding wire 1A. There are five signal lead parts 12A, which are connected to the gate terminal of the IGBT 20B by the bonding wire 1B. There are five signal lead parts 13A, which are connected to the gate terminal of the IGBT 20C by the bonding wire 10.

Note that as the bonding wire 1A, the bonding wire 1B, and the bonding wire 10, for example, an aluminum thin line may be used.

As illustrated in FIG. 5A, FIG. 5B, and FIG. 6, the connection part 503 of the wiring part 500 is connected to the surface of the heat spreader 40 by a solder 2A. The connection part 503 is connected to the voltage detection lead part 118 (118A) via the one end 501, and is also connected to the power lead part 114 (114A) via the other end 502.

Furthermore, as illustrated in FIG. 5A and FIG. 5B, the power lead part 15A is connected to the emitter terminal of the IGBT 20A by the solder 2B, and is also connected to the anode of the diode 30A by the solder 2C. The power lead part 16A is connected to the emitter terminal of the IGBT 20B by the solder 2D, and is also connected to the anode of the diode 30B by the solder 2E. The power lead part 17A is connected to the emitter terminal of the IGBT 20C by the solder 2F, and is also connected to the anode of the diode 30C by the solder 2G.

Note that the power lead parts 114(114A), 15(15A), 16(16A), 17(17A) have wider widths than those of the signal lead part 11(11A).

As illustrated in FIG. 6, to the heat spreader 40, the collector terminal of the IGBT 20A is connected by the solder 191, and the cathode of the diode 30A is connected by the solder 192. Furthermore, as described above, to the heat spreader 40, the connection part 503 of the wiring part 500 is connected by the solder 2A.

Thus, the wiring part 500 has a potential equal to that of the collector terminal of the IGBT 20A, and the potential of the collector terminal of the IGBT 20A may be detected via the wiring part 500 and the voltage detection lead part 118.

An X direction and a Y direction are defined as illustrated in FIG. 4A, FIG. 4B, FIG. 5A, and FIG. 5B. The X direction and the Y direction are orthogonal to each other in a plane including the wiring part 500.

As illustrated in FIG. 4A and FIG. 5A, the wiring part 500 is positioned on the outermost side in the X direction of the lead frame 100.

Furthermore, in the wiring part 500, the one end 501 is connected to the voltage detection lead part 118A, a part of the guide frame 119A, and a part of the guide frame 119B, in the Y direction. Furthermore, the other end 502 is connected to the connection part 503, the power lead part 114A, and a part of the guide frame 119C.

That is to say, in a state before cutting off the guide frame 119 from the lead frame 100, the wiring part 500 acts as a guide frame between the voltage detection lead part 118A, the part of the guide frame 119A, the part of the guide frame 119B and the connection part 503, the power lead part 114A, the part of the guide frame 119C.

As described above, the wiring part 500 functions as a guide frame included in the lead frame 100. Therefore, the length, the width, the thickness, the shape, etc., of the wiring part 500 are to be set to provide a sufficient level of strength by which bending, deforming, etc., do not occur in the voltage detection lead part 118A, the part of the guide frame 119A, the part of the guide frame 119B and the connection part 503, the power lead part 114A, the part of the guide frame 119C.

As described above, as illustrated in FIG. 4A and FIG. 5A, the wiring part 500 of the lead frame 100 according to the embodiment functions as a guide frame in a state before cutting off the guide frame 119; and as illustrated in FIG. 4B and FIG. 5B, the wiring part 500 of the lead frame 100 functions as wiring in a state after cutting off the guide frame 119.

Next, a description is given of the connection relationship in a case where the power module 200 according to the embodiment is used as the top arm of the inverter 303 illustrated in FIG. 3.

In this example, the IGBT 20A and the diode 30A are connected to the U phase, the IGBT 20B and the diode 30B are connected to the V phase, and the IGBT 20C and the diode 30C are connected to the W phase.

In this case, the power lead part 114, which is connected to the collectors of the IGBTs 20A through 20C and the cathodes of the diodes 30A through 30C via the connection part 503, constitute a positive terminal side (input terminal) P1 of the inverter 303 (see FIG. 3) of the electric automobile driving device 300.

Therefore, the voltage detection lead part 118, which is connected to the power lead part 114 via the wiring part 500, can detect the input voltage (voltage of positive terminal side (input terminal) P1) of the inverter 303.

The power lead part 15, which is connected to the emitter of the IGBT 20A and the anode of the diode 30A, constitutes a U phase terminal P3 of the inverter 303 (see FIG. 3).

The power lead part 16, which is connected to the emitter of the IGBT 20B and the anode of the diode 30B, constitutes a V phase terminal P4 of the inverter 303 (see FIG. 3).

The power lead part 17, which is connected to the emitter of the IGBT 20C and the anode of the diode 30C, constitutes a W phase terminal P5 of the inverter 303 (see FIG. 3).

Furthermore, as the bottom arm of the inverter 303 illustrated in FIG. 3, a power module may be used, which is formed by removing the voltage detection lead part 18 from the power module 60 of the comparative example, and adding a lead part connected to the emitter terminals of the switching elements Q4, Q6, Q8 of FIG. 3.

The lead part connected to the emitter terminals of the switching elements Q4, Q6, Q8 is constituted by a negative terminal side (input terminal) P2 of the inverter 303 (see FIG. 3). Furthermore, the collector terminals of the switching elements Q4, Q6, Q8 of the power module of the bottom arm are to be connected to the U phase terminal P3, the V phase terminal P4, and the W phase terminal P5, respectively.

Next, a description is given of the mold resin part 150, the cooling plate 170, and the insulating sheet 180.

The cooling plate 170 is formed of a material having high heat conductivity. For example, the cooling plate 170 may be formed of a metal such as aluminum. The cooling plate 170 has fins 171 provided on the bottom side. The number of fins 171 and the arrangement format of the fins 171 may be arbitrary, unless otherwise mentioned. Furthermore, the configuration (shape, height, etc.) of the fins 171 may be arbitrary. For example, the fins 171 may be realized by straight fins or pin fins in a staggered arrangement, etc. In a state where a semiconductor module 1 is mounted, the fins 171 are in contact with a cooling medium such as cooling water and cooling air. As described above, the heat from the IGBTs 20 and the diodes 30 generated when the IGBTs 20 and the diodes 30 are driven, is transferred from the fins 171 of the cooling plate 170 to the cooling medium via the heat spreader 40, the insulating sheet 180, and the cooling plate 170, so that the cooling of the IGBTs 20 and the diodes 30 is realized.

Note that the fins 171 may be formed together with the cooling plate 170 as a single body (for example, aluminum die casting), or may be combined with the cooling plate 170 by welding, etc., to form a single body. Furthermore, the cooling plate 170 may be constituted by joining a single metal plate with another metal plate with fins by bolts, etc.

The insulating sheet 180 is constituted by, for example, a resin sheet, and enables high heat conductivity from the heat spreader 40 to the cooling plate 170 while maintaining electric insulation between the heat spreader 40 and the cooling plate 170. The insulating sheet 180 has a larger outer shape than that of the bottom face of the heat spreader 40.

Note that the insulating sheet 180 preferably directly joins the heat spreader 40 and the cooling plate 170, without using a solder, a metal film, etc. Accordingly, compared to the case of using a solder, the heat resistance can be lowered, and the procedures can be simplified. Furthermore, the cooling plate 170 side does not require surface processing for soldering. For example, the insulating sheet 180 is made of the same resin material (epoxy resin) as the mold resin part 150 described below, and is joined with the heat spreader 40 and the cooling plate 170 by the pressure and the temperature during the molding of the mold resin part 150.

As illustrated in FIG. 4B, FIG. 5B, and FIG. 6, the mold resin part 150 is formed by molding, with resin, the IGBTs 20, the diodes 30, the parts of the signal lead parts 11, 12, 13 and the power lead parts 15, 16, 17 excluding the edge part of the wiring member, parts of the voltage detection lead part 118 excluding the edge part, the wiring part 500, the heat spreader 40, the cooling plate 170, and the insulating sheet 180.

That is to say, the mold resin part 150 is the part for sealing inside the main elements of the power module 200 (the IGBTs 20, the diodes 30, the parts of the signal lead parts 11, 12, 13 and the power lead parts 15, 16, 17 excluding the edge part of the wiring member, parts of the voltage detection lead part 118 excluding the edge part, the wiring part 500, the heat spreader 40, and the insulating sheet 180) with respect to the top side of the cooling plate 170. The resin used as the mold resin part 150 may be, for example, epoxy resin.

Furthermore, the edge parts of the wiring members of the signal lead parts 11, 12, 13 and the power lead parts 15, 16, 17, the edge part of the voltage detection lead part 118A, and the power lead part 114 are exposed from the mold resin part 150.

The final shapes of the edge parts of the wiring members of the signal lead parts 11, 12, 13 and the power lead parts 15, 16, 17, the edge part of the voltage detection lead part 118A, and the power lead part 114, are realized by lead cutting and forming, after the mold-sealing by the mold resin part 150.

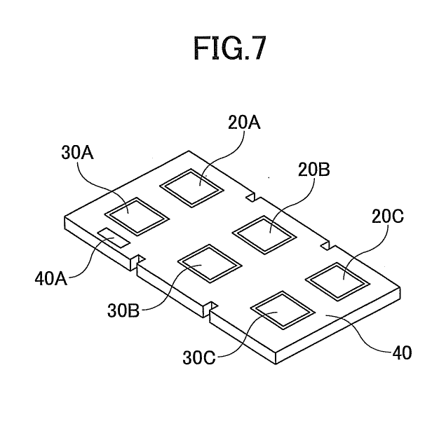

Next, a description is given of a manufacturing method of the power module 200 according to the embodiment, with reference to FIGS. 7 through 11.

FIGS. 7 through 11 illustrate manufacturing procedures of the power module 200 according to the embodiment in a stepwise manner.

First, as illustrated in FIG. 7, the IGBTs 20A through 20C and the diodes 30A through 30C are mounted on the heat spreader 40 by soldering. The collector terminals of the IGBTs 20A through 20C are connected to the heat spreader 40 by the solders 191, and the cathodes of the diodes 30A through 30C are connected to the heat spreader 40 by the solders 192 (see FIG. 6).

Note that a connection part 40A indicated on the surface of the heat spreader 40 expresses the position where the connection part 503 of the lead frame 100 is connected later.

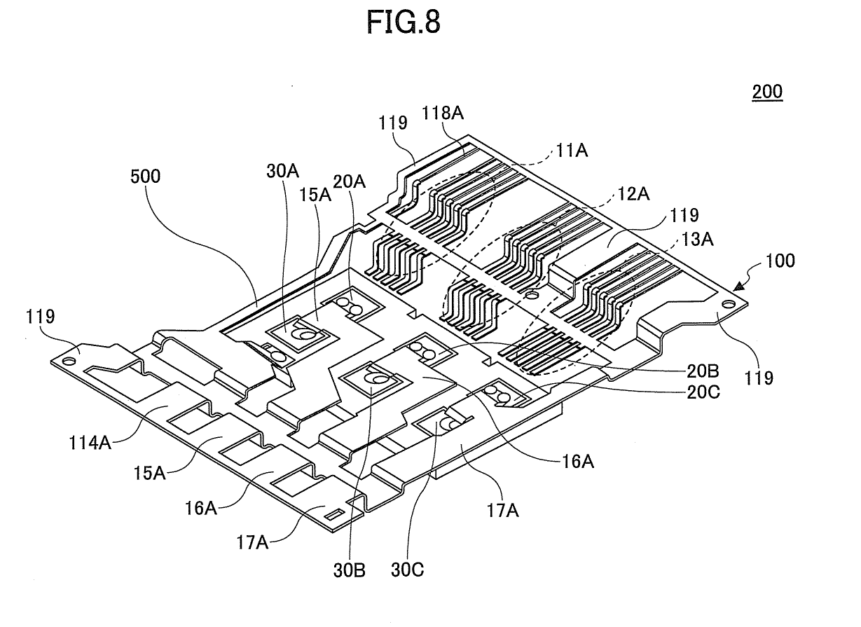

Next, as illustrated in FIG. 8, on the IGBTs 20A through 20C and the diodes 30A through 30C mounted on the heat spreader 40, the lead frame 100 is placed and positioned, and the IGBTs 20A through 20C, the diodes 30A through 30C, and the lead frame 100 are connected by the solders 2B through 2G.

At this time, the connection part 503 and the connection part 40A of the heat spreader 40 are also joined by the solder 2A.

Furthermore, the signal lead parts 11A, 12A, 13A, and the gate terminals of the IGBTs 20A, 20B, 20C are connected by the bonding wires 1A, 1B, 1C.

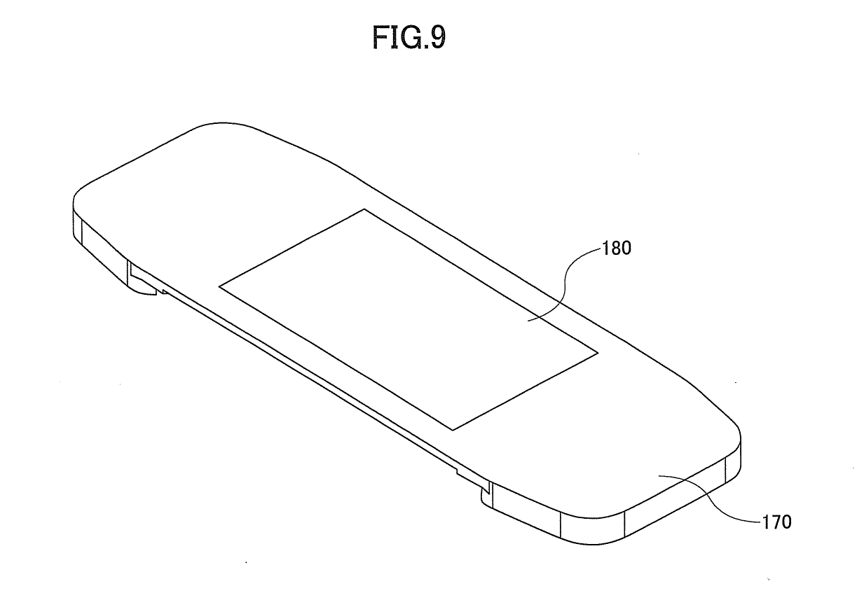

Next, as illustrated in FIG. 9, the insulating sheet 180 is pasted on a predetermined position on the cooling plate 170. At this time, for example, the insulating sheet 180 is temporarily pasted onto the surface of the heat spreader 40 by heating.

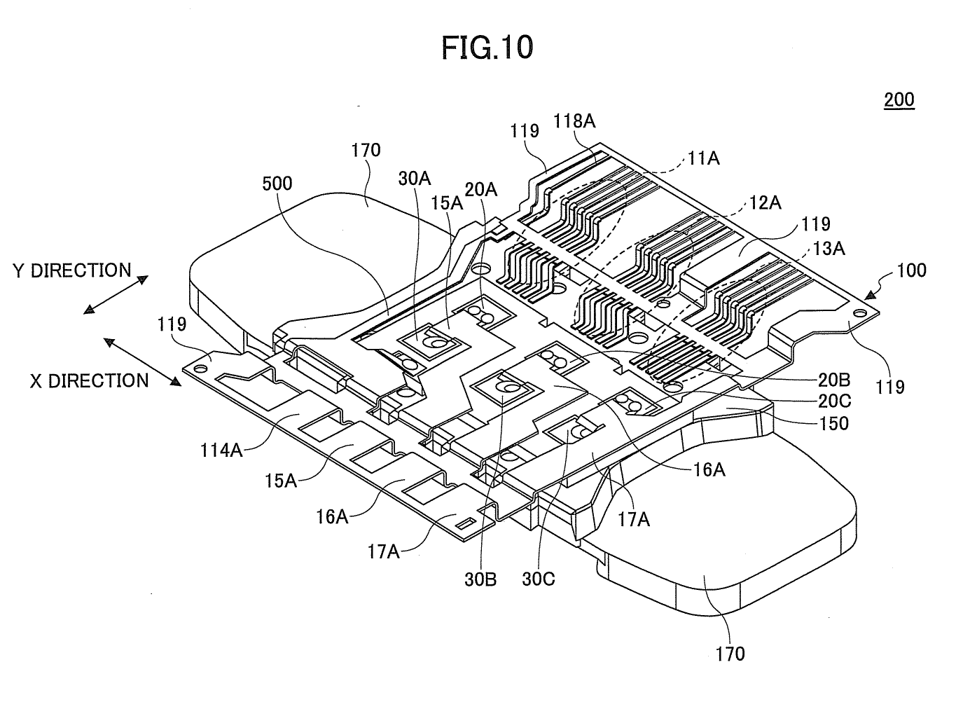

Next, as illustrated in FIG. 10, on the insulating sheet 180 pasted on a predetermined position on the cooling plate 170, the heat spreader 40 is placed, on which the IGBTs 20A through 20C, the diodes 30A through 30C, and the lead frame 100 are soldered as illustrated in FIG. 8, and the mold resin part 150 is formed by transfer molding.

FIG. 10 transparently illustrates the mold resin part 150, similar to FIG. 4A. In this state, the edge parts of the wiring members of the signal lead parts 11, 12, 13 and the power lead parts 15, 16, 17, the edge part of the voltage detection lead part 118A, and the power lead part 114 are exposed from the mold resin part 150.

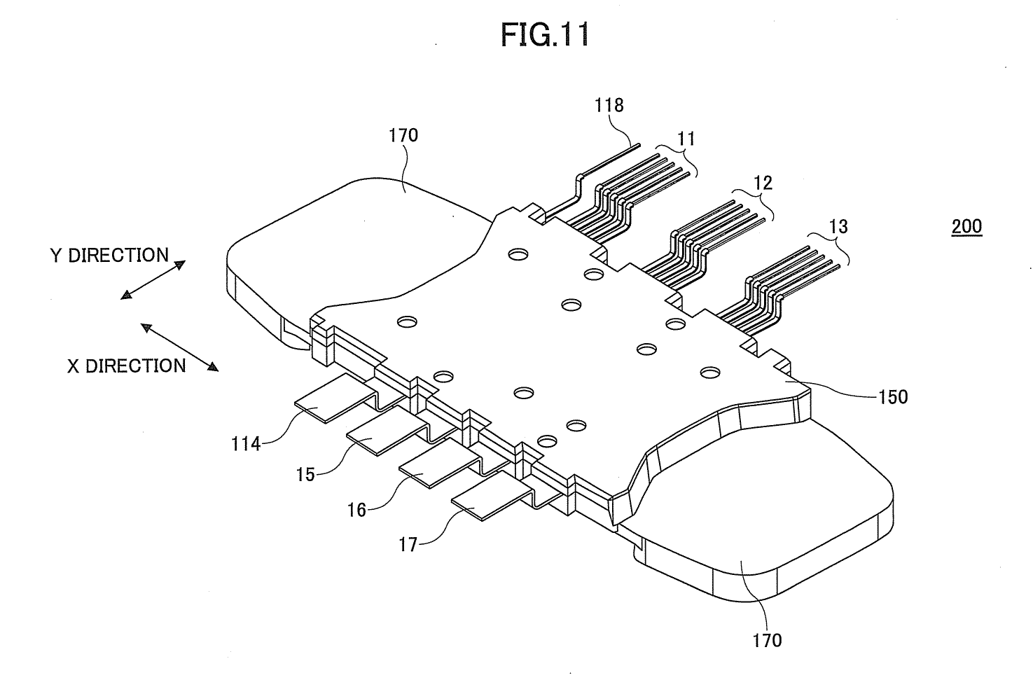

Then, finally, when the guide frame 119 is cut off by using a mold, as illustrated in FIG. 11, the power module 200 is completed.

As described above, according to the present embodiment, the lead frame 100 including the wiring part 500 is provided, which functions as a guide frame in a state before cutting off the guide frame 119, and which functions as wiring as illustrated in FIG. 4B and FIG. 5B in a state after the guide frame 119 is cut off.

In the lead frame 10 of the comparative example, the entire guide frame 19 (see FIG. 1 and FIG. 2) is discarded after being cut off, and therefore the material yield has been low.

Meanwhile, in the lead frame 100 according to the present embodiment, the wiring part 500 functions as a guide frame in a state before the guide frame 119 is cut off, and the wiring part 500 functions as wiring as illustrated in FIG. 4B and FIG. 5B in a state after the guide frame 119 is cut off.

That is to say, in the lead frame 100 according to the present embodiment, part of the guide frame is used as the wiring part 500 without being cut off.

Therefore, in the present embodiment, the lead frame 100 is provided, by which the material yield is improved.

Furthermore, as it can be seen by comparing the lead frame 10 of the comparative example illustrated in FIG. 1 with the lead frame 100 according to the present embodiment illustrated in FIG. 5A, in the lead frame 100 according to the present embodiment, the wiring part 500 is accommodated inside the mold resin part 150.

Thus, compared to the lead frame 10 of the comparative example, in the lead frame 100 according to the present embodiment, the wiring part 500 and the structure around the wiring part 500 can be reduced in size in a planar view.

Therefore, compared to the lead frame 10 of the comparative example, the lead frame 100 according to the present embodiment can be manufactured with less metal materials.

For this reason also, in the present embodiment, the lead frame 100 is provided, by which the material yield is improved.

Furthermore, as the lead frame 100 according to the present embodiment can be manufactured with less metal materials, compared to the lead frame 10 of the comparative example, a larger number of lead frames 100 can be manufactured from the same amount of metal materials.

Furthermore, the lead frame 100 according to the present embodiment can be reduced in size in a planar view smaller than that of the lead frame 10 of the comparative example, and therefore the mold used for cutting off the guide frame 119 can be reduced in size.

Furthermore, in the wiring part 500 of the lead frame 100 according to the present embodiment, the one end 501 is connected to the voltage detection lead part 118, and the connection part 503 is connected, by the solder 2A, to the collector terminal of the IGBT 20A of the top arm of the inverter 303 (see FIG. 3) via the heat spreader 40.

Therefore, only by connecting the connection part 503 to the heat spreader 40 by the solder 2A, the voltage detection lead part 118 can be used as a terminal for monitoring the input voltage (voltage of positive side terminal (input terminal) P1) of the inverter 303.

That is to say, there is no need to connect the detection lead part 18 by the bonding wire 3 (see FIG. 2) as in the lead frame 10 of the comparative example, so that the manufacturing procedures can be reduced, and the power module 200 can be provided at low cost.

Furthermore, in the lead frame 100 according to the present embodiment, the guide frame 119 can be cut off in a state where the wiring part 500 functioning as part of the guide frame is sealed by the mold resin part 150.

Therefore, when cooling is performed after heat is applied for forming the mold resin part 150, the wiring part 500 functioning as part of the guide frame of the lead frame 100 is fixed by the mold resin part 150 so that deforming and warping do not occur, and therefore lead cutting can be performed with high precision.

Furthermore, accordingly, it is possible to prevent deforming and warping from occurring in the edge part of the wiring member of the signal lead parts 11, 12, 13 and the power lead parts 15, 16, 17, the edge part of the voltage detection lead part 118A, and the power lead part 114. Accordingly, the reliability in the joint parts of the solders 2A through 2G is enhanced, and the shelf life of the joint parts of the solders 2A through 2G is increased.

Furthermore, the wiring part 500 functioning as part of the guide frame of the lead frame 100 is accommodated inside the mold resin part 150, and therefore the area B (see FIG. 1) is not generated between the mold resin part 50 (see FIG. 2) and the guide frame 19, as in the case of the lead frame 10 of the comparative example.

Accordingly, also in the case where metal friction is occurring in the mold used for lead cutting, a burr is prevented from being formed in the mold resin part 150 near the wiring part 500.

Note that the power module 200 may include other configurations (for example, part of the element of a boost DC/DC converter for driving a running motor). Furthermore, the power module 200 may include other elements (capacitor, reactor, etc.) together with the semiconductor device. Furthermore, the power module 200 is not limited to the semiconductor module constituting the inverter. Furthermore, the power module 200 is not limited to an inverter for a vehicle, but may be realized as an inverter used for other purposes (a train, an air-conditioner, an elevator, a refrigerator, etc.).

In the above, the lead frame and the power module according to an exemplary embodiment of the present invention are described; however, the present invention is not limited to the specific embodiments disclosed herein, and variations and modifications may be made without departing from the scope of the present invention.

The present application is based on and claims the benefit of priority of Japanese Priority Patent Application No. 2011-143033, filed on Jun. 28, 2011, the entire contents of which are hereby incorporated herein by reference.

### DESCRIPTION OF REFERENCE SYMBOLS

100 lead frame
11, 11A, 12, 12A, 13, 13A signal lead part
114, 114A, 15, 15A, 16, 16A, 17, 17A power lead part
118, 118A voltage detection lead part
119 guide frame
20, 20A, 20B, 20C IGBT
30, 30A, 30B, 30C diode
40 heat spreader
150 mold resin part
170 cooling plate
180 insulating sheet
200 power module
500 wiring part

1. A lead frame comprising:
a plurality of first leads extending to one side of an area in which a semiconductor device is disposed in a planar view;
a plurality of second leads extending to another side that is opposite the one side of the area in which the semiconductor device is disposed in a planar view;
a third lead arranged outside of one of the plurality of first leads positioned at an edge of the plurality of first leads in a planar view; and
a wiring part that is connected to the third lead, acts as a part of a guide frame of the plurality of first leads, the plurality of second leads, and the third lead, and acts as a wiring connected to the third lead after parts of the guide frame other than the part of the guide frame have been cut off.

2. The lead frame according to claim 1, wherein
the wiring part includes one end connected to the third lead and another end connected to a predetermined terminal of the semiconductor device.

3. The lead frame according to claim 1, wherein
the predetermined terminal to which the wiring part is connected is a terminal used for monitoring a voltage of the semiconductor device.

4. The lead frame according to claim 1, wherein
the third lead is a lead used for monitoring a voltage.

5. The lead frame according to claim 1, wherein
the semiconductor device is an IGBT, and
the predetermined terminal is a collector terminal of the IGBT.

6. The lead frame according to claim 1, wherein
at least part of the wiring part is covered by a mold resin together with the semiconductor device.

7. The lead frame according to claim 1, wherein
each of the plurality of second leads has a wider width than that of each of the plurality of first leads.

8. The lead frame according to claim 1, further comprising:
a fourth lead that is connected to the wiring part, and arranged outside one of the plurality of second leads positioned at an edge corresponding to the one of the plurality of first leads positioned at the edge.

9. A power module comprising:
the lead frame according to claim 1; and
the semiconductor device.
